(19) United States
(12) Patent Application Publication
(10) Pub. No.: US 2012/0013197 A1
(43) Pub. Date: Jan. 19, 2012

(54) ELECTRICAL LINE CONDITIONER

(76) Inventor: George DEWBERRY, Palm Springs, CA (US)

(21) Appl. No.: 13/198,284

(22) Filed: Aug. 4, 2011

Related U.S. Application Data
(63) Continuation-in-part of application No. 11/906,435, filed on Oct. 2, 2007, now abandoned.

(51) Int. Cl. H05K 9/00; C25D 5/34; H01R 43/00; C25D 11/02

(52) U.S. Cl. 307/89; 205/333; 205/210; 29/825

(57) ABSTRACT

An electrical line conditioner or energy conservation device, a process of manufacturing thereof, and a method of use thereof. The energy conservation device, or electrical line conditioner, comprises at least two different electrochemically oxidized aluminum alloy units that may be placed near electrical lines or electrical panels or surround electrical lines to reduce energy consumption without compromising performance of a load. A first electrochemically oxidized aluminum alloy unit may be violet, a second electrochemically oxidized aluminum alloy unit may be black. The electrical line conditioner may further comprise a spacer and a band to secure the electrical line conditioner to electrical lines. The electrical line conditioner is produced using an anodizing process.

### CROSS-REFERENCE TO RELATED APPLICATIONS

The present application is a continuation-in-part of U.S. application Ser. No. 11/906,435,filed Oct. 2, 2007, presently abandoned. Application Ser. No. 11/906,435 is the subject of a concurrently-filed Petition to Revive under 37 C.F.R.§1.137(b). Application Ser. No. 11/906,435 claims priority from U.S. Provisional Application No. 61/937,148, filed Jun. 26, 2007.

### STATEMENT REGARDING FEDERALLY SPONSORED RESEARCH OR DEVELOPMENT

Not applicable.

### NAMES OF THE PARTIES TO A JOINT RESEARCH AGREEMENT Not applicable.

### INCORPORATION-BY-REFERENCE OF MATERIALS SUBMITTED ON A COMPACT DISC

Not applicable.

### BACKGROUND OF THE INVENTION

1. Field of the Invention

This invention relates to energy conservation devices, their method of production, and their method of use.

2. Description of Related Art Including Information Disclosed Under 37 CFR 1.97 and 37 CFR 1.98.

Energy conservation has been a subject of concern for many years due to the limited practical energy resources and the dangerous byproducts produced. Currently, over 70% of the energy generated comes from fossil fuels. These fossil fuels are converted to oil and natural gas. The burning of oil and natural gas is converted to electrical energy with carbon dioxide released as the byproduct. The production of carbon dioxide is purported to be involved in the greenhouse effect.

Many attempts have been made to harness energy from alternative sources such as wind, water, and solar. These efforts although successful are far less efficient than the amount of energy produced by fossil fuels. In addition, nuclear energy has also been used as an alternative source of energy but the dangers of nuclear reactors have stifled its popularity.

For the time being, fossil fuels remain the major source of energy production and energy conservation technology may be the best way to reduce fossil fuel consumption. Thus, there is a need for a safe device that can be quickly and easily produced in mass quantities and easily installed in residential homes or commercial buildings to reduce the consumption of electrical energy without significantly decreasing the load usage. One method for decreasing electrical energy consumption without significantly decreasing the performance of an electrical device is to increase the efficiency of conductance of electricity.

Without being bound by theory, it is believed that the efficiency of conductance of electricity is lost to several factors, such as electromagnetic interference with the 50 to 60 cycle noise given off by electrical lines and the skin effect. The electromagnetic interference given off by radioactivity, microwaves, cell phone waves, radio waves and solar distortions interfere with the smooth flow of the electrons through a conductor. The 50 to 60 cycle noise given off by electrical lines may also interfere with the smooth flow of the electrons through a conductor. The skin effect is the tendency for current to flow at the surface of the conductor; thereby effectively increasing the resistance of the conductor.

Therefore, a device that could block the electromagnetic interference and counteract the noise (such as the 60 cycle noise in the U.S. and the 50 cycle noise in many European countries) and induce the electrons to flow in a synchronous manner may increase the efficiency of electron flow through a conductor. In addition, by redistributing the current flow throughout the conductor, the resistance can be reduced, thereby creating a more efficient flow of current through the conductor. A more efficient flow of current would result in less electrical energy being required to generate the same amount of power.

The product of this invention may utilize other mechanisms to enhance electrical efficiency.

### BRIEF SUMMARY OF THE INVENTION

The present invention is directed to an energy conservation device, referred to as an electrical line conditioner, comprising an electrochemically oxidized aluminum alloy that may be placed near electrical lines or electrical panels to block unwanted electromagnetic interference and 50 to 60 cycle noise, counteract the skin effect, and/or increase electrical flow thereby increasing the overall efficiency of electrical conductance and decrease the amount of total energy required to drive a load.

The present invention is also directed to the method of using an energy conservation device comprising the steps of placing the energy on an electrical panel or wrapping the energy conservation device around an electrical line branch conductor or a group of electrical lines. A plurality of electrical energy devices may be used in electrical panels. In one embodiment, the energy conservation devices are arranged in a triangular orientation.

The energy conservation device is made by electrochemically oxidizing an aluminum alloy to a predetermined specification.

### BRIEF DESCRIPTION OF THE SEVERAL VIEWS OF THE DRAWINGS

FIG. 1A is a perspective view of an embodiment of the current invention;

FIG. 1B is a side view of the cutaways indicated at 1B;

FIG. 1C is a perspective view of the embodiment shown in FIG. 1A rolled up;

FIG. 2A is a close up of a portion of the perspective view of the embodiment shown in FIG. 1A;

FIG. 2B is a close up perspective view of an embodiment of the conditioner units;

FIG. 3 is a diagram of an electrical panel with the energy conservation device installed;

FIG. 4 is a diagram another electrical panel with the energy conservation device installed;

FIG. 5 is a diagram of another electrical panel with the energy conservation device installed;

FIG. 6 is another embodiment of the current invention;

FIG. 7 is an embodiment of the current invention installed on an electrical panel;

FIG. 8 is a front view of another embodiment of the current invention;

FIG. 9 is a diagram of the embodiment of FIG. 8 installed on an electrical panel;

FIG. 10 is a flowchart of the process of electrochemically oxidizing the aluminum alloy units;

### DETAILED DESCRIPTION OF THE INVENTION

The detailed description set forth below in connection with the appended drawings is intended as a description of presently-preferred embodiments of the invention and is not intended to represent the only forms in which the present invention may be constructed or utilized. The description sets forth the functions and the sequence of steps for constructing and operating the invention in connection with the illustrated embodiments. However, it is to be understood that the same or equivalent functions and sequences maybe accomplished by different embodiments that are also intended to be encompassed within the spirit and scope of the invention.

The current invention is directed towards an energy conservation device, also referred to as an electrical line conditioner 100, to decrease energy consumption of a load without compromising the performance of the load. Without being bound by theory, it is believed that the electrical line conditioner 100 cancels out distortions at the sub-atomic level in the magnetic field of an electric current by resonating frequencies into that field and synchronizing the flow of electrons through the conductive material. The electrical line conditioner 100 also counteracts the skin effect thereby allowing the electrons to flow throughout the conductive material in an electric or electrical line 306 rather than only at the surface of the conductive material. Allowing the electrons to flow throughout the conductive material rather than only at the surface is believed to decrease the resistance in the conductive material. Synchronizing the electron flow and reducing the resistance is believed to create a more efficient flow of electricity. Since the flow of electricity is more efficient, less total energy is believed to be required to power a load, such as any appliance.

All statements herein regarding the reason why Inventor's discovery operates the way it does are based on Inventor's belief regarding it and are presently being investigated. Such beliefs do not in any way diminish or negate Inventor's discovery.

At present, the inventor believes that the electrical line conditioner operates through interaction with the magnetic field, making the electrical circuit more conductive. A frequency is created in the magnetic field which transfers to the electric field and increases conductivity. One explanation is that the presence of foreign chromium atoms in the structure of corundum, a crystalline form of aluminum oxide (Al₂O₃). In this case, a chromium atom has taken the place of an aluminum atom. These two atoms are approximately the same size, but the slight difference causes a defect in the lattice. This creates a disturbance of the bond energy and results in the necessary frequency, which transfers to the electric field and increases conductivity.

Recently research conducted by a third party independent laboratory has shown that the device does increase heat transfer rates. The device has been shown to make electric circuits more conductive, possibly due to partial room temperature superconductivity.

It is possible, that the electrical line conditioner 100 can utilize other mechanisms to increase current flow, decrease resistance in a conductor, achieve electrical efficiency, or otherwise decrease the electrical energy required to power a load without decreasing the performance of the load when compared to a load without the use of the electrical line conditioner 100.

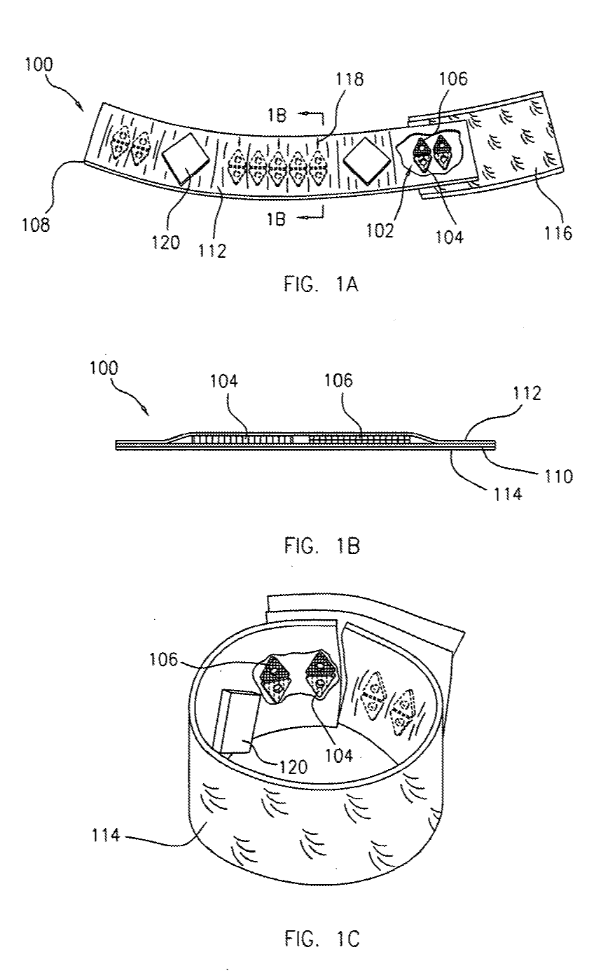

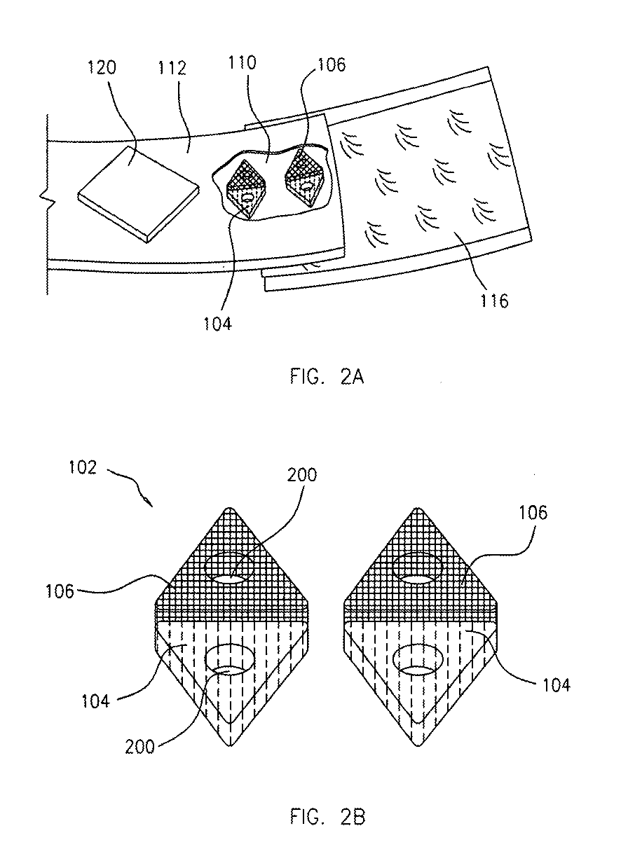

As shown in FIG. 1, the energy conservation device or electrical line conditioner 100 comprises a conditioner unit 102. The conditioner unit comprises a first metal unit and a second metal unit, wherein placing the first and second metal units near an electrical line connected to a load conditions the electrical line so as to decrease the amount of electrical energy required to power the load without diminishing the performance of the load when compared to a non-conditioned electrical line, in particular, an electrical line without the conditioner units installed or near the electrical line.

The electrical line may be any line that conducts electricity to power a load such as an appliance or any other electrical device. The electrical line may carry alternating current as in residential and commercial buildings.

A variety of different types of metal can be used, such as aluminum, titanium, zinc, magnesium, and the like. Preferably, the metal units are anodized. In one embodiment, the conditioner unit comprises a first anodized metal unit and a second anodized metal unit, wherein the first anodized metal unit is a violet color and the second anodized metal unit is a black color.

In some embodiments, the metal units comprise an aluminum alloy unit. Preferably, the conditioner unit comprises a first aluminum alloy unit 104 and a second aluminum alloy unit 106. In some embodiments, the first aluminum alloy unit 104 and the second aluminum alloy unit 106 are arranged adjacent to each other.

The base material of the first and second aluminum alloy units 104, 106 are substantially the same. In addition, the electrochemical oxidation process or anodizing process of the two aluminum alloy units 104, 106 are similar. A difference between the first aluminum alloy unit 104 and the second aluminum alloy unit 106 is the dye color selected to differentiate the first aluminum alloy 104 from the second aluminum alloy 106. In one embodiment, the first aluminum alloy unit 104 is a shade of violet and the second aluminum alloy unit 106 is a shade of black.

The first and second aluminum alloy units 104, 106 each comprise at least 80% aluminum, at least 0.1% magnesium, and at least 0.05% chromium. In one embodiment, the first and second aluminum alloys 104, 106 comprise approximately 90% to approximately 99.5% aluminum, approximately 0.5% to approximately 5.1% magnesium, and approximately 0.09% to approximately 0.25% chromium. In another embodiment, the first and second aluminum alloy units 104, 106 are aluminum alloy 5052 sold by Central Steel & Wiring Company, which contains approximately 97.25% aluminum, approximately 2.5% magnesium, and approximately 0.25% chromium.

In some embodiments, the first and second aluminum alloy units 104, 106 are each triangular in shape. However, the first and second aluminum alloy units 104, 106 may be any geometric shape, such as a circle, a rectangle, a square, and the like. In addition, each aluminum alloy unit 104, 106 may be of any size. In some embodiments, the aluminum alloy units 104, 106 are the same size. In certain embodiments, each aluminum alloy unit 104, 106 comprises a hole 200. The hole 200 may be any shape and any size and located anywhere on the aluminum alloy units 104, 106. One feature of the hole 200 is that it facilitates the anodization process by allowing the aluminum alloy units 104, 106 to be perched on pins. In some embodiments, the first and second aluminum alloy units 104, 106 are 1.5 mm thick equilateral triangles with 7 mm legs and a circular hole 200 two mm in diameter located in the center of the aluminum alloy units 104, 106. In some embodiments, the aluminum alloy units 104, 106 do not have any holes.

The first and second aluminum alloy units 104, 106 are placed adjacent to each other to form the conditioner unit 102. In some embodiments, the first and second aluminum alloy units 104, 106 are in contact with each other. In other embodiments, the first and second aluminum alloy units may be separated from each other. In some embodiments, the conditioner unit 102 is arranged such that the second aluminum alloy unit 106 is closer to a load than the first aluminum alloy unit 104. In other words, the direction from the first aluminum alloy unit 104 to the second aluminum alloy unit 106 is generally the direction of the current flow.

In some embodiments, the first and second aluminum alloy units 104, 106 may be separated from each other. The first and second aluminum alloy units 104, 106 may even be separated by an electrical line. In some embodiments, the second aluminum alloy unit 106 may be mounted on the first aluminum alloy unit 106. In embodiments where the aluminum alloy units are mounted on top of each other, the second aluminum alloy unit 106 may be the same size or smaller than the first aluminum alloy unit 104. The second aluminum alloy unit 106 may be mounted anywhere on the first aluminum alloy unit 104. Preferably, the second aluminum alloy unit 106 is mounted at or near the center of the first aluminum alloy unit 104.

The electrical line conditioner 100 may comprise a single conditioner unit 102 or a plurality of conditioner units 102. In embodiments comprising a plurality of conditioner units 102 the electrical line conditioner 100 may further comprise a band 108, wherein the first aluminum alloy unit is placed adjacent to the second aluminum alloy unit in each of the plurality of conditioner units and each conditioner unit is relatively oriented on the band such that the first aluminum alloy units of each conditioner unit are aligned along one side of the band and the second aluminum alloy units of each conditioner unit are aligned along a second side of the band opposite the first anodized metal units. The band 108 comprises a strip 110 having a first side and a second side opposite the first side.

The conditioner units 102 may be affixed to the first side of the strip 110 such that the conditioner units 102 are aligned linearly with each first aluminum alloy unit 104 of each conditioner unit 102 oriented on the same side or direction on the strip 110. The strip 110 may be made of any material, such as plastic, fabric, metal, etc. In some embodiments, the strip 110 is a piece of MYLAR®.

The band further comprise a front cover 112 attached to the first side of the strip to help secure the conditioner units 102 as well as keep the conditioner units 102 clean. The front cover 112 can be made of any material such as plastic, fabric, metal, etc. In one embodiment, the front cover 112 is made of cotton fabric. The front cover 112 can be attached to the strip 110 by any means.

The band may further comprise a back cover 114. The back cover 114 may further comprise a fastening mechanism 116 so that the conditioner units can be secured to an electrical line. In some embodiments, the fastening mechanism 116 is attached to the back cover 114. In some embodiments, the fastening mechanism 116 is a hook-and-loop fastening mechanism such as that sold under the trademark VELCRO®. The purpose of the fastening mechanism 116 is to secure the strip 110 to an electrical line, preferably in a circular arrangement. A circular arrangement will allow the electrical line conditioner 100 to be wrapped around an electric or electrical line 306 or a group of electric lines. As such, any type of fastening mechanism 116 such as glue, tape, adhesive, hook-and-loop mechanism, clips, clamps, buttons, and the like will suffice.

An indicia 118 can be positioned on either side of the band 108 indicating the proper orientation of the electrical line conditioner 100 on the electric line 306. For example, a simple marking or arrow can be placed on the side of the second aluminum alloy unit 106 to indicate that this side must be positioned closest to the load. It is important to have the proper positioning of the electrical line conditioner 100 as improper positioning could result in increased energy expenditure. Alternatively, the indicia 118 may mark the first aluminum alloy unit 104 to indicate that this side should be positioned away from the load or against the current flow.

In some embodiments, the electrical line conditioner 100 further comprises at least one spacer 120. The spacer 120 may be affixed to the front cover 112. Alternatively, the spacer 120 may be affixed to an aluminum alloy unit. The purpose of the spacer 120 is to keep the conditioner units 102 at an appropriate distance from the electric lines for proper functioning. In addition, the spacer 120 prevents the conditioner units 102 from acting as an antenna for disruptive energy waves. The spacer 120 contains material, such as crystals or microcrystals that can interact with a wide range of frequencies of electric and magnetic fields. Preferably, the spacer 120 is made from the Pulsor® energy stabilizer card. In some embodiments, the spacer 120 has a surface approximately 14 mm in length by 14 mm in width with a thickness of about 1 mm. However, the spacer 120 can be any shape and a variety of sizes. In addition, the spacer 120 may be placed anywhere on the conditioner unit 102.

The distance between the electrical line conditioner 100 and the electrical line 306 varies with the size of the conditioner unit 102. The larger the conditioner unit 102, the further away the electrical line conditioner 100 can be from the electrical line 306.

Without being bound by theory, it is believed that the energy conservation device or electrical line conditioner 100 provides a method of increasing electrical efficiency by dissipating a skin effect, distributing a plurality of electrons throughout the conductor, and synchronizing an electron flow within a conductor, thereby decreasing a resistance and creating a more efficient electrical conductance resulting in less total energy required to power a load. This may be accomplished by placing at least one electrical line conditioner 100 near an electric line 306 with the second aluminum alloy unit 106, or the black aluminum alloy unit, closest to the load or pointing in the direction of current flow.

Thus, a method of conserving an electrical energy without compromising the performance of a load is achieved by placing at least one anodized metal unit near an electrical line thereby resulting in a reduction in the electrical energy required to power the load without diminishing the performance of the load relative to an electrical energy required to power the load without at least one anodized metal unit placed near the electrical line.

In some embodiments, a first anodized metal unit and a second anodized metal unit are arranged such that the electrical line is situated between the first anodized metal unit and the second anodized metal unit. In other embodiments, the first anodized metal unit can be placed adjacent to the second anodized metal unit to form a conditioner unit 102 and the conditioner unit 102 can be placed near the electrical line.

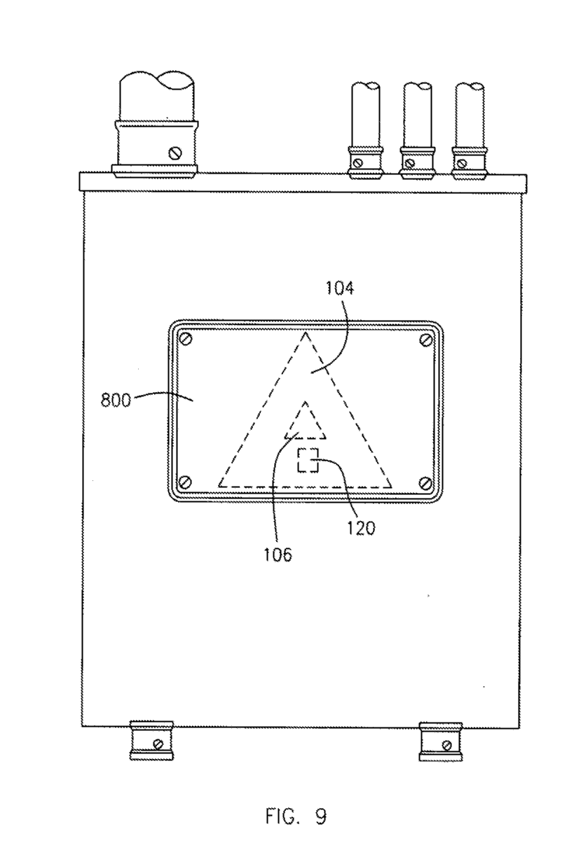

A plurality of conditioner units may be placed near the electrical line. The electrical line conditioner 100 may be positioned near a branch circuit conductor in a main panel 302, a sub panel 304, or both. In some instances, the electrical line conditioner 100 maybe positioned in the subpanel 304 closest to the load. In other instances, the electrical line conditioner 100 may be positioned outside the subpanel 304 as shown in FIG. 9. In another embodiment, the electrical line conditioner 100 is on the electric line 306 after the main panel 302 or subpanel 304 but before the load.

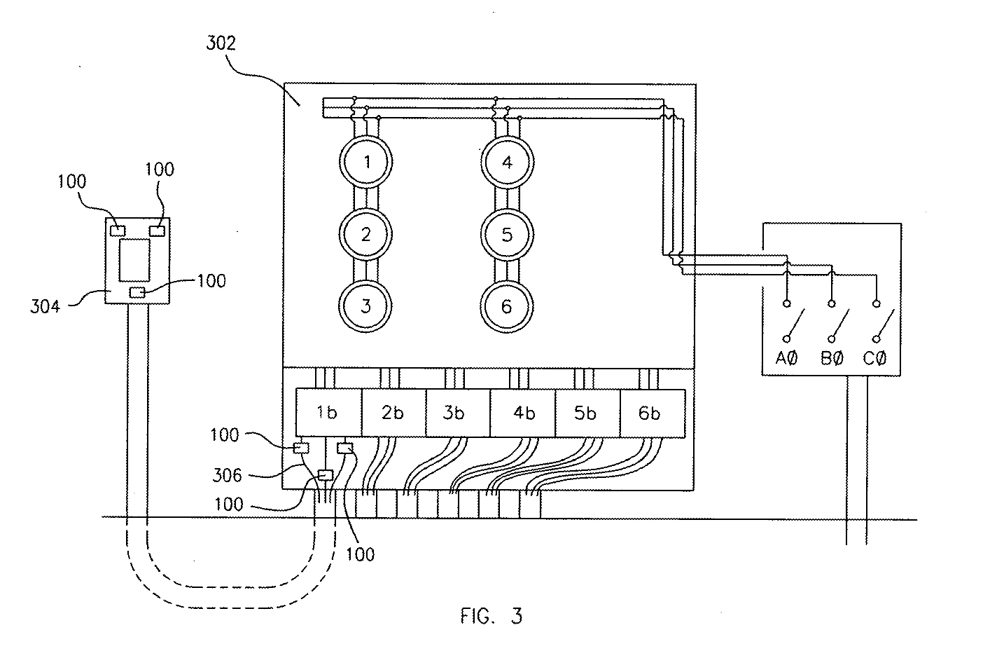

A plurality of electrical line conditioners 100 may be positioned in different locations in the panel 302 or subpanel 304. Three electrical line conditioners 100 may be positioned in an electrical panel in a triangular formation as shown FIGS. 3 through 7. Preferably, no electrical line conditioner 100 should be closer than five inches to each other. In addition, major loads should not be more than 100 feet away from the electrical line conditioner 100.

The electrical line conditioner 100 may be applied to all electrical components, including but not limited to single phase (residential units) or three phase (commercial units). The electrical line conditioner 100 may be applied to AC powered currents. The electrical line conditioner 100 may be installed at or near an electrical line 306 by wrapping the electrical line conditioner 100 around an electric line 306 or a group of electric lines in a main panel 302 or in a subpanel 304.

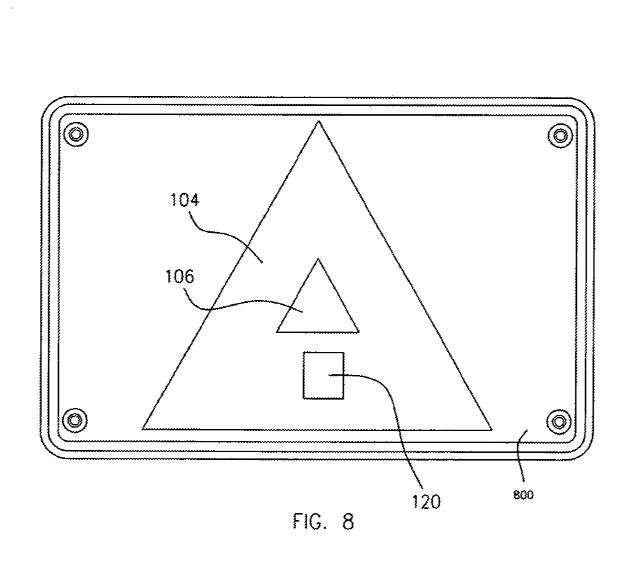

In other embodiments, as shown in FIGS. 8 and 9, a single large conditioner unit may be placed on the front of an electrical panel and a second large conditioner unit 102 on the back. FIG. 8 shows a large conditioner attached to a housing 800. The housing 800 may be made of any sturdy material such as metal or plastic. The housing 800 may further comprise a lid to enclose and protect the conditioner unit during transport or storage. In use, the housing may have attachment means so as to attach to the electric panels. The attachment means can be adhesives, screws holes, hook and loop, and the like. The housing 800 may be attached to the inside or the outside of the electric panel, thereby affixing the conditioner unit between the electric panel and the housing 800. This allows the conditioner unit to have its effects on the electrical wires while allowing the housing to provide protection to the conditioner unit.

In other embodiments, the conditioner units may be affixed directly on to the inside or the outside of the electric panel. Attaching the conditioner unit to the inside of the electric panel may offer more protection from inclement weather and vandals.

In embodiments utilizing the large conditioner units, the second aluminum alloy unit may be placed on top of the first aluminum alloy unit. In addition, the spacer may be placed on top of the first aluminum alloy unit as shown in FIG. 8.

Positioning the electrical line conditioner 100 on the inside of the house close to the load or inside a panel 302 will reduce the potential for interference or tampering with the electrical line conditioner 100.

In general, conserving electrical energy within the scope of this invention comprises placing a first set of conditioner units 102 near a group of electric lines 306 at a first location. The first set of conditioner units 102 comprises a violet colored aluminum alloy unit 104 and a black colored aluminum alloy unit 106. The first set of conditioner units 102 are arranged such that the black aluminum unit 104 is closest to the load. In some embodiments, the black aluminum unit 106 points in the direction of current flow. In another words, when a current flows, the current flows in a direction from the violet anodized aluminum metal unit towards the black anodized metal unit. Additional steps may include placing a second set of conditioner units 102 near the group of electric lines at a second location, and placing a third set of conditioner units near the group of electric lines at a third location, wherein the first, second, and third set of electrochemically oxidized conditioner units 102 form a triangular pattern. Each set of conditioner units 102 comprises a black aluminum piece and a violet aluminum piece. Each set of conditioner units 102 are arranged such that the black aluminum alloy unit 106 is closest to the load. In another embodiment, each set of conditioner units 102 are arranged such that the black aluminum alloy unit 106 points in the direction of the flow of current.

In some embodiments, conserving electrical energy comprises placing a set of conditioner units 102 on the main panel 302 or on the subpanel 304 or both. In such embodiments, the second aluminum alloy unit 106 may be mounted on the first aluminum alloy unit 104. In addition, the spacer 120 may also be mounted on the first aluminum alloy unit 104. The first aluminum alloy unit 104 may be mounted on a backing 700. The backing can then be secured to the panel either on the outside or on the inside. In some embodiments, a first conditioner unit may be secured to the front side of the panel and a second conditioner unit may be mounted on the back of the panel. The mounting can be any type of fastening mechanism, either temporary or permanent. In some embodiments, adhesive or glue is used.

Mounting the conditioner unit 102 onto a panel via a backing 700 provides protection to the conditioner unit 102 from the environment as well as from tampering, vandalism, and theft.

In one embodiment, conserving electrical energy comprises wrapping a first set of conditioner units 102 around a group of electric lines at a first location. Additional steps may include wrapping a second set of conditioner units 102 near the group of electric lines at a second location, and wrapping a third set of conditioner units 102 near the group of electric lines at a third location, wherein the first, second, and third set of conditioner units 102 form a triangular pattern.

### Method of Production

A method of producing an energy conservation device or electric line conditioner that can decrease an amount of electricity required to power a load without decreasing a performance of the load, comprises the steps of anodizing a plurality of metal pieces; dyeing a first set of metal pieces a shade of violet; dyeing a second set of metal pieces a shade of black; and sealing the plurality of metal pieces.

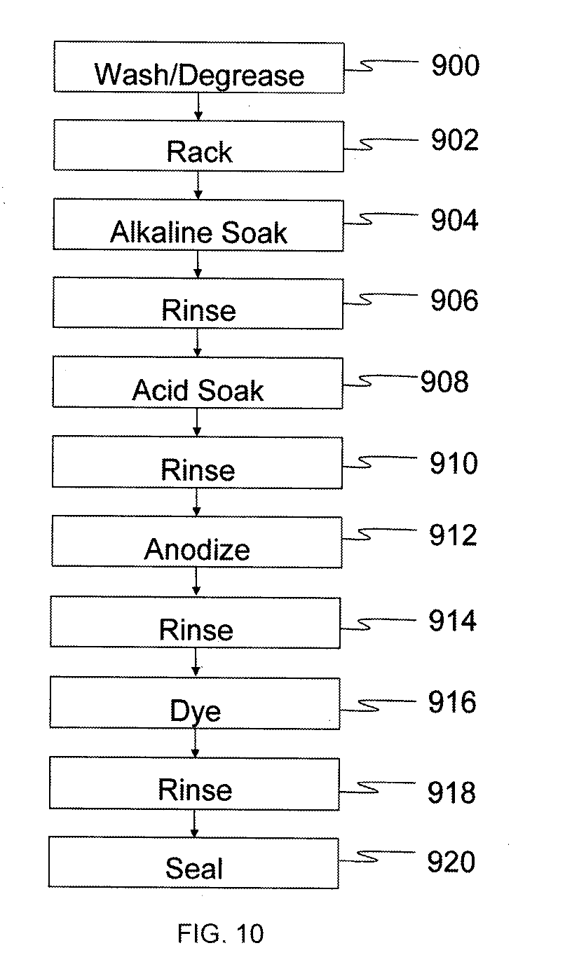

In some embodiments, the plurality of metal pieces comprise aluminum alloy. The aluminum alloy units 104, 106 are electrochemically oxidized by using an anodization process, as summarized briefly in FIG. 10. The first aluminum alloy unit 104 and the second aluminum alloy unit 106 are generated similarly except for the dye color. First, each aluminum alloy unit 104, 106 is cleaned and degreased 900, if necessary, to remove any debris or grease. The aluminum alloy units 104, 106 comprise aluminum, magnesium and chromium. In some embodiments, the aluminum alloy units 104, 106 comprise at least 80% aluminum, at least 0.1% magnesium, and at least 0.05% chromium. In another embodiment, the aluminum alloy units comprise approximately 90% to approximately 99.5% aluminum, approximately 0.5% to approximately 5.1% magnesium, and approximately 0.09% to approximately 0.25%. In another embodiment, the first and second aluminum alloy units 104, 106 are aluminum alloy 5052 sold by Central Steel & Wiring Company, which contains approximately 97.25% aluminum, approximately 2.5% magnesium, and approximately 0.25% chromium.

Next, the cleaned aluminum alloy units 104, 106 are placed on a conductive support member or rack 902. The support member may be made of titanium to reduce corrosion. The support member can be a pin, a spline, an umbrella, a basket, or any other type of support member to hold the aluminum alloy units 104, 106 during the oxidation process. In some embodiments, the aluminum alloy units 104, 106 are placed on a pin. To facilitate this process, the aluminum alloy units 104, 106 may comprise a hole 200 through which the pin may be inserted.

Having been secured on a support member 902, the aluminum alloy units 104, 106 are etched to remove a thin layer of aluminum using an alkaline solution 904, for example a caustic soda. In some embodiments, the alkaline solution comprises approximately 1% to approximately 30% caustic soda. The alkaline solution may comprise approximately 5% to approximately 15% caustic soda. In another embodiment, the alkaline solution comprises approximately 10% of a caustic soda. In one embodiment, aluminum alloy units 104, 106 are soaked in alkaline for approximately 5 seconds to approximately 30 minutes. Preferably, the aluminum alloy units 104, 106 are soaked for approximately 5 minutes to approximately 10 minutes. The alkaline soak is also conducted at a temperature of approximately 100 degrees Fahrenheit to approximately 200 degrees Fahrenheit. In some embodiments, the alkaline soak is conducted at a temperature of approximately 120 degrees Fahrenheit to approximately 160 degrees Fahrenheit.

After the alkaline soak, the aluminum alloy units 104, 106 are cleaned with a water rinse 906 for at least approximately 30 seconds. The water rinse may be conducted at ambient temperature; however, the water rinse may also be conducted with cold, warm, or hot water.

Next, the aluminum alloy units 104, 106 are exposed to a bright dip 908, or an acidic solution for at least approximately 15 seconds to further remove unwanted debris and provide a smooth surface. The acidic solution may contain approximately 75% to approximately 99% sulfuric acid and approximately 1% to approximately 25% nitric acid. The acidic solution may comprise approximately 90% sulfuric acid and approximately 6% to 10% nitric acid. The aluminum alloy units 104, 106 are then rinsed 910 again in water for at least approximately 30 seconds.

After the bright dip, the aluminum alloy units 104, 106 are anodized 912 in an acid solution. The acid may be a chromic acid or a sulfuric acid. DC current is applied to the acid solution through the rack, such that the rack holding the aluminum alloy becomes the anode. This causes hydrogen to be released at the cathode and oxygen to be released at the anode containing the aluminum alloy units. Oxygen released at the aluminum alloy units, thereby effectively oxidizes the aluminum alloy to create aluminum oxide crystals on the surface of the aluminum alloy units. The aluminum oxide crystals form pores on the surface of the aluminum alloy.

The voltage used during the anodizing process ranges from approximately 15 volts to approximately 21 volts. In one embodiment, 18 volts was used. The temperature of the acid solution ranges from approximately 60 degrees Fahrenheit to approximately 90 degrees Fahrenheit. In one embodiment, the temperature of the acid solution ranges from approximately 66 degrees Fahrenheit to approximately 74 degrees Fahrenheit. After the anodizing process, the aluminum alloy units 104, 106 are rinsed 914 again in water for at least approximately 30 seconds and preferably at ambient temperatures.

After the anodizing process, the aluminum alloy units are exposed to a dye 916. The first aluminum alloy unit 104 is exposed to a violet dye. The color can be any shade of violet in the electromagnetic spectrum of approximately 380 nanometers to approximately 450 nanometers. The shade of violet is approximately 400 nanometers to approximately 420 nanometers. In some embodiments, the violet dye was SANODYE® MF Violet 3D Powder manufactured by Clariant, used at a concentration of approximately 2.0 grams/liter to approximately 5.0 grams/liter.

The second aluminum alloy unit 106 is exposed to a black dye. Each aluminum alloy unit may be exposed to its respective dye for approximately 30 seconds to approximately 20 minutes. In some embodiments, the aluminum alloy units are exposed to their respective dyes for approximately 1 minute to approximately 15 minutes until the desired shade of color is achieved. The aluminum alloy units may be exposed to the dye solution at temperatures of approximately 100 degrees Fahrenheit to approximately 200 degrees Fahrenheit. In some embodiments, the dye solution is approximately 130 degrees Fahrenheit to approximately 160 degrees Fahrenheit. After exposing the aluminum alloy units to the dyes, the aluminum alloy units are rinsed 918 again in water for at least approximately 30 seconds, preferably at ambient temperatures.

After the dyeing step, the aluminum alloy units 104, 106 are sealed 920 in a sealant. The sealant may be hot deionized water, TEFLON®, nickel acetate, hot dichromate, and the like. The aluminum alloy units 104, 106 may be exposed to the sealant for approximately 1 minute to approximately 60 minutes. In some embodiments, the aluminum alloy units 104, 106 are exposed to the sealant for approximately 10 minutes to approximately 20 minutes. The temperature of the sealant when exposed to the aluminum alloy units 104, 106 may be approximately 150 degrees Fahrenheit to approximately 212 degrees Fahrenheit. In some embodiments, the temperature of the sealant is approximately 190 degrees Fahrenheit to approximately 210 degrees Fahrenheit. After sealing, the aluminum alloy units 104, 106 are rinsed in water for at least approximately 30 seconds, preferably at ambient temperatures.

This same anodization process may be utilized for other types of metal pieces besides aluminum alloy such as, titanium, zinc, magnesium and the like.

Once the electrochemically oxidized aluminum alloy units 104, 106 are prepared, the electrical line conditioner 100 can be assembled. The first aluminum alloy unit 104 is placed adjacent to the second aluminum alloy unit 106 to form a conditioner unit 102. In some embodiments, the second aluminum alloy unit 106 may be mounted on the first aluminum alloy unit 104. A plurality of conditioner units may be aligned in the same orientation along a strip such that all the first aluminum alloy unit 104 are on one half or portion of the strip and all the second electrochemically oxidized aluminum alloy unit 106 are on the other half or portion of the strip 110 as shown in FIG. 1A. In one embodiment, the strip 110 is flexible. The plurality of conditioner units 102 may be secured with a front cover 112 to form the electrical line conditioner 100. Spacers 120 may be added on top of the front cover 112 to adjust the distance between the conditioner units 102 and an electric line 306 and to prevent the conditioner units from acting as antennas for disruptive energy waves. The strip 110 may be provided with a fastening mechanism on the opposite side of the front cover 112. The electrical line conditioner 100 can then be wrapped around an electric line 306 or a group of electric lines and fastened in place. In some embodiments, a plurality of electrical line conditioners 100 may be positioned in an electrical panel 302. Preferably, the plurality of electrical line conditioners 100 are positioned in the electrical panel 302 in a triangular formation.

### Examples of Installation

Proper installation is critical for the electrical line conditioner to work effectively. In some embodiments, three electrical line conditioners 100 may be placed inside an electrical panel. In some embodiments, the electrical line conditioners 100 are load direction sensitive, thus the electrical line conditioners 100 should be installed with the black anodized metal units pointed towards the load, and away from the disconnecting menus. To facilitate proper installation, an indicia 118 may be placed on the band 108 to indicate the location of the black anodized metal units or the violet anodized metal units.

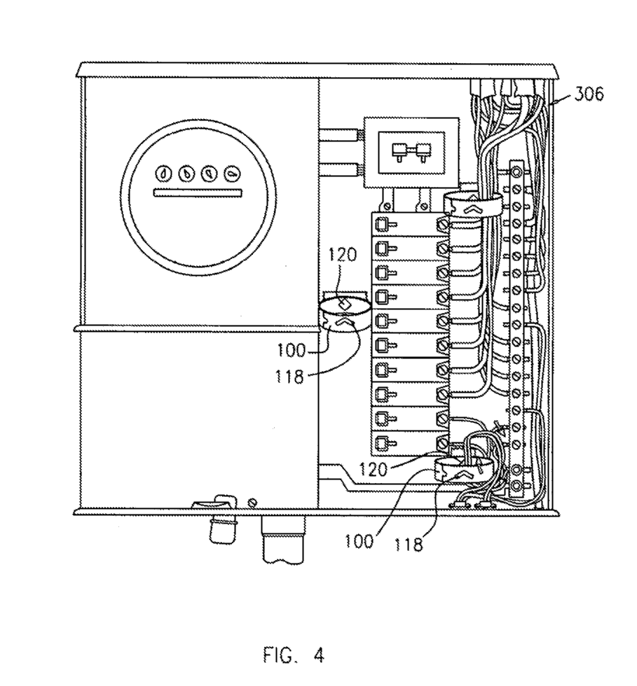

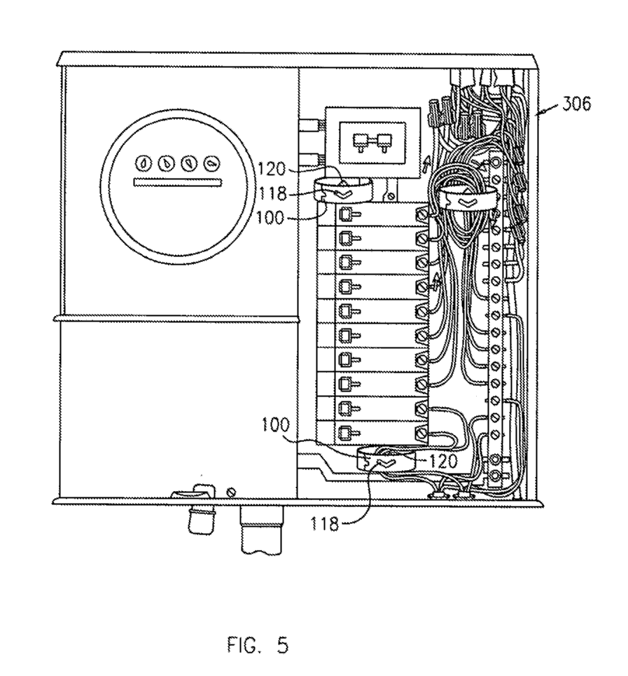

In some embodiments, the electrical line conditioners 100 may be oriented in the same direction in the panel such that all the first anodizing metal units face in the same direction as each other and all the second anodized metal units face in the same direction as each other but in the opposite direction relative to the first anodized metal units. In order to keep all electrical line conditioners 100 oriented and in the same direction, it is often necessary to create a loop in some of the branch conductors so as to have an ideal positioning of the bands as shown in FIGS. 4 and 5.

In some embodiments, the spacers 120 comprise a surface, wherein the surface of the spacer of a first electrical line conditioner does not directly face the surface of the spacer of a second electrical line conditioner. In other words, a ray projecting orthogonally from the surface of the spacer of the first electrical line conditioner should not orthogonally intersect the surface of the spacer of the second electrical line conditioner. To facilitate the proper orientation, the spacers 120 may be attached to the front cover 112 and the indicia 118 may be placed on the back cover 114 directly behind the spacer 120. This facilitates quick identification of the location of a spacer 120 so that the spacer 120 in a first electrical line conditioner 100 can be properly oriented relative to the spacer 120 of a second electrical line conditioner 100.

For example, spacers 120 of all the electrical line conditioners inside an electrical panel may be arranged such that the surfaces of each spacer 120 face either the front door of the electrical panel or the back wall of the electrical panel. In such an orientation, the ray projecting orthogonally from the surface of the spacer of the first electrical line conditioner would not orthogonally intersect the surface of the spacers in the second line conditioner. By contrast, if the surface of a spacer of a first electrical line conditioner were to directly face the surface of a spacer of a second electrical line conditioner, then the surfaces would be parallel and a ray projecting from the surface of the spacer from the first electrical line conditioner would intersect orthogonally with the surface of the spacer of the second electrical line conditioner. Such an orientation may cancel out the effect of the electrical line conditioners.

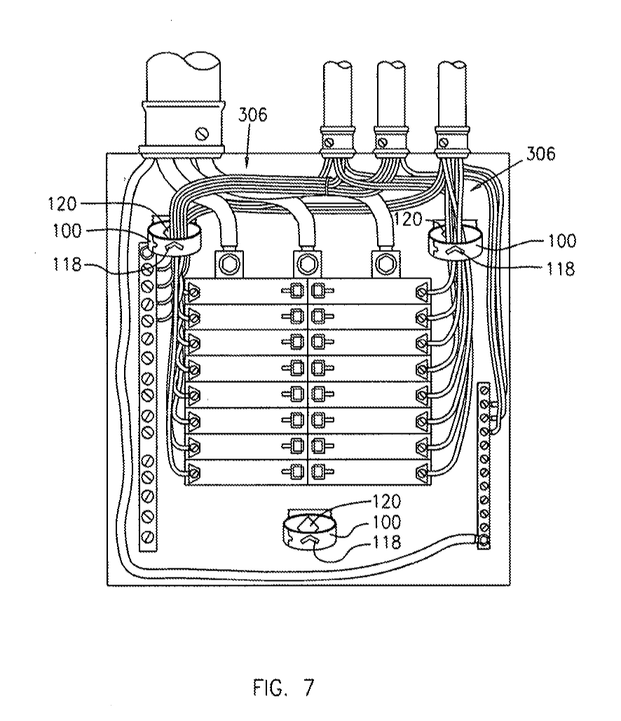

The spacers may be positioned along the front cover 112 such that when the band 108 is wrapped into a circular formation a first and second spacer is positioned opposite each other. In some embodiments, it is desirable to use a third electrical line conditioner as a “ghost ring” where all of the electrical lines in an electrical panel is adequately encircled by two electrical line conditioners and the third electrical line conditioner is positioned inside the electrical line conditioner so as to complete a triangular formation. This third electrical line conditioner would be arranged in a circular formation as if it were to wrap around an electrical line as shown in FIGS. 4 and 7. A fastening means may be employed to affix the third electrical line conditioner in place.

In embodiments employing the triangular configuration, the preferred triangular formation is the equilateral triangle. Other triangular formations include the isosceles triangle and the right triangles. In general, two of the electrical line conditioners may be placed along the top, bottom or sides such that a base of a triangle is defined along the top bottom or the side. In each case, it is preferred that each electrical line conditioner is placed at least approximately two to approximately five inches from another electrical line conditioner. Preferably, the distance between electrical line conditioners is at least approximately five inches.

In embodiments utilizing a ghost ring, the electrical line conditioner serving as the apex of the triangle may be the ghost ring. Since the base of the triangle may be positioned along the top, bottom, or the side, the apex of the triangle may also be positioned at the top, the bottom, or the side of the electrical panel.

Preferably, the triangle defined by the electrical line conditioner is as large as possible constrained only by the size of the electrical panel. Great care must be taken that the electrical line conditioners are installed in positions inside the enclosure where covers and dead fronts do not bend or misshape the electrical line conditioner after closing the panel. Ideally, the electrical line conditioner should remain in a nearly perfect circular shape wrapped around the electrical lines. The electrical lines should be manipulated in such a way that their tension or orientation does not misshape or detach the electrical line conditioner in any way.

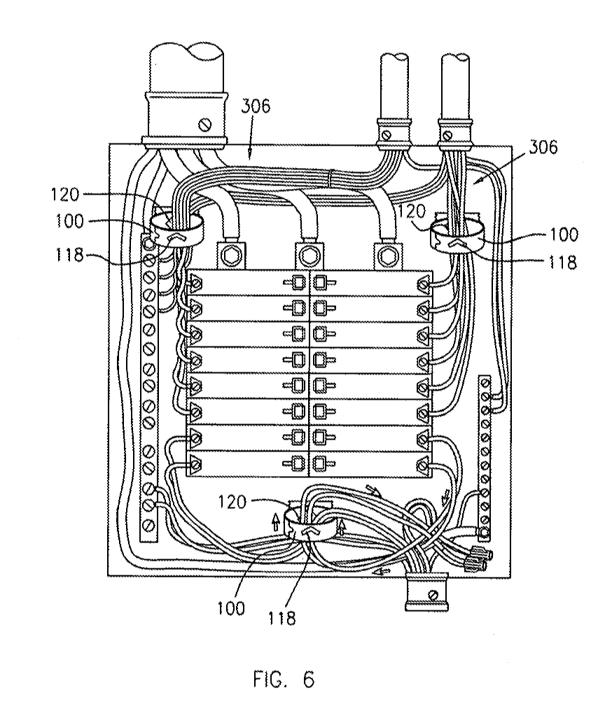

In any installation utilizing a plurality of electrical line conditioners it is preferred that all electrical line conditioners have the same orientation. In order to determine what this orientation should be the installer should assess how many of the electrical lines leading to the load are being routed through the top and bottom of the electrical panel, relative to the breaker. If most of the electrical lines leading to the load are leaving the top of the electrical panel, as is most common, the electrical line conditioner should be oriented such that the black aluminum alloy unit is oriented toward the top. This leaves fewer electrical lines to extend or reconfigure so that they pass through the other electrical line conditioners effectively. For example, as shown in FIG. 6, most of the electrical lines are leaving through the top of the electrical panel on the right side. There are a few electrical lines leaving the bottom of the panel. The two electrical line conditioners located at the top are oriented with the indicia pointed upwards since that follows the direction of current flow out towards the load. In general, the third electrical line conditioner located at the bottom of the electrical panel would be oriented with the indicia pointing downward to indicate the direction of the current flow out of the panel towards the load. In order to maintain consistency in the orientation of the electrical line conditioners, however, the electrical lines have been extended to loop in an upward direction prior to exiting at the bottom of the electrical panel so that the third electrical line conditioner can wrap around the electrical line with the indicia pointing upwards and in the direction of the current flow.

In some embodiments, electrical line conditioners may be oriented horizontally rather than vertically.

In some embodiments, a set of electrical line conditioners may be installed in every electrical panel associated with a building or a residence, be it the main disconnect, the distribution panel, or the sub-panel. All electrical panels for outbuildings and equipment should be considered and included. Additionally, if a load, is further than 125 feet away from the electrical panel, an extra electrical line conditioner may be utilized on the electrical line near the load itself. This single device acts as a “booster” to the field strength in long circuits.

It should be noted that neutral or grounded conductors are preferably not included in the devices. The preferred conductors incorporated are the energized (live) electrical lines from the circuit breakers to the branch circuit loads themselves. In disconnects and distribution centers, sub panel feeders may be encircled together within the bands to provide greater field strength.

In most commercial applications, there are sufficient panels such that loads are rarely greater than 125 feet away. If this is cause for concern, these loads may be boosted by adding single booster rings at the equipment itself. Examples of this being necessary include remote walk-ins, case refrigeration equipment, manufacturing equipment, or rooftop HVAC equipment. Most of these will have space for a device booster at the appliance or in its associated controls.

In the preferred embodiment, three devices should be installed. Frequently, because of the higher degree of engineering and neatness in many commercial panels coupled with the fact that loads often leave the top of commercial panels through conduits, it may be necessary to use the ‘ghost ring’ technique. Frequently, it will be possible to encircle all of the load wiring in a commercial panel in just two electrical line conditioners. However, a third electrical line conditioner should be installed for enhanced performance. It is not recommended to install electrical line conditioners inside gutters or wire way troughs, as the likelihood of improper orientation or device field cancellation is higher.

Finally, it has been tested and proven that the electrical line conditioners work well in common commercial panel types. Their efficacy and field strength has not been tested in larger twin 200 enclosures. Using the electrical line conditioners in large switchgear style enclosures is acceptable, if the electrical line conditioners are arranged in a triangular orientation. In these cases, sub-feeds and branch conductors to large equipment may be incorporated. If transformers are being used in a 480 to 120/208 step-down scenario, the appropriate course is to encircle the branch conductors feeding 480 volt dedicated equipment, excluding transformer feeds, and to protect the loads on the transformed service in the appropriate panel enclosure, after transformation has occurred. As of this writing, it is yet to be determined what the effect will be, if any, in encircling the transformer primary feeds.

The electrical line conditioners are also ideal for the home in reducing household energy consumption. In many cases, however, the enclosures supplying a residence are smaller and have less wirewav space around the internal equipment. This is due in large part to the standardized use of meter/breaker combination enclosures where all of the circuits in the home are fed from one narrow cabinet adjacent to the meter base. Frequently, as described previously, it is necessary to adapt the shape and orientation of the electrical line conditioners slightly to allow for maximum effectiveness. In most cases, this involves narrowing the base aspect of the triangle, and maximizing the vertical height, or widening the base of the installed triangle, and shortening the vertical axis.

The bands of the electrical line conditioners may be color-coded as an indicator for residential applications or commercial use. For example, the bands may be colored a high visibility green for residential use and orange for commercial use. Other types of indicator markings, colors, designs, patterns and the like can be used to differentiate electrical line indicators for residential use and commercial use.

With residential installations, it is more likely that branch circuits will leave the enclosure from the bottom and even sides of the panel, creating a necessity to lengthen and loop these conductors for proper orientation of the electrical line conditioners.

In the case of a larger residence with outbuildings, pool equipment, AC banks, attached garages and workshops and even guest quarters, it is more likely that the installer will encounter equipment that is more akin to commercial service enclosures. Frequently, with these estates, a main disconnecting switchgear acting as a distribution center to several sub-panels will be present. If it is feasible to do so, a set of devices may be installed in this switchgear protecting the panel sub-feeds and any equipment branch circuits that may be present. As with a commercial application, additional sets should be installed in all sub-panel enclosures, as well.

As described previously, in embodiments employing the triangular arrangement, all three electrical line conditioners in an installation should have the same orientation relative to each other, and be positioned such that the load side of the circuit leaves the ring in the direction of the second aluminum alloy unit. In many cases, this is only possible by extending some branch circuit conductors, or moving circuit breakers to new positions within the apparatus to add length to the branch conductor itself. The reason for the need of this modification is simple. After assessing the loads in an enclosure, the installer should take note that, in many cases, the circuit wiring leaves the enclosure in at least two directions. There should be enough length on the branch circuit conductors such that an upward or downward sweeping loop is created in these circuits, however appropriate, as shown in FIGS. 4 and 5. The electrical line conditioner is then installed on the alternate path of this loop, so that it is directionally load oriented and maintains the same orientation relative to the other devices. Essentially, this loop is being used to change the direction of the load orientation for a short course, so as to provide ample space to fit the device in its proper orientation. The extra branch circuit conductor is the desired effect of either modification, as this allows the installer to create the change in orientation as necessary. Basically, if a breaker can be moved without changing the load signature or balance, this is the most desirable course for modification, as it reduces extra junction points in the conductors. In many cases, however, it is necessary to add a foot or two of extra wire to each of the existing wires on the affected branch circuits, and create the alternate path loop in this manner.

The Installer should exercise caution when deciding to swap breaker positions. If the wire must be removed from the terminal of the breaker to assist in the extension, care should be exercised to note its original location, and re-feed it accordingly. Additionally, before moving any circuit breaker locations, the installer should double-check the voltage present phase-to-phase and phase-to-ground for all phases present. In some installations, especially in older municipal areas, you will encounter ‘wild’ or ‘high’ leg three phase panels, wherein one phase has a 208-volt signal to ground (usually c phase). The results of swapping IIP loads to these positions in the panel can be expensive and exceedingly dangerous to people and property. For example, 208 volts applied to a 110-volt circuit can and will burn up motors, compressors, circulating fans, computers and communications equipment, and presents unique hazards to the installer and owner. Finally, if breakers are moved in the course of the installation, it is the responsibility of the installer to re-label the panel board with regard to the new circuit locations.

When extending the branch circuit conductors in the panel to create a loop, several points of caution should be observed. First, the conductor should always be extended with wire of the same or greater gauge. Using a smaller gauge, lesser-rated conductor as an extension presents a fire and failure hazard. Second, only UL approved connecting means should be employed in these junctions. Wire nuts, butt-splices, and other forms of insulated crimp connectors are appropriate. On the other hand, soldering connections, crimping with uninsulated connectors or ‘twisting and taping’ the connections all present serious hazards and can cause junction failure and electrical fires, as well. Finally, when using a wire nut to, secure a junction, the installer shall make sure that the junction ends are suitably twisted together to make a secure mechanical connection. The spring tension of the wire nut itself should not be depended upon to maintain this junction. These improperly attached junctions can cause arcing, load dimming, and circuit failure, as they are prone to come apart over time. In every case where a junction and extension are necessary, care and attention to detail are the ultimate guideline to maintaining this modification over time.

### Examples

### Residential Use

During the months of August through October 2006 experiments were conducted with the electrical line conditioner 100 in Palm Desert, Calif. The electrical line conditioner 100 was applied to main panels and subpanels of seven residential units. Two, three, or four electrical line conditioners 100 were utilized in each panel or subpanel. In tests using three electrical line conditioners 100, the triangular arrangement was used. During the one month prior to installing the electric power conditioner, the amount of electrical energy consumed ranged from about 2120 KW to about 5053 KW, with an average of about 3884 KW. During the month that the electrical line conditioner 100 was installed, the amount of electrical energy consumed ranged from about 1375 KW to about 3680 KW with an average of about 2685. Thus, the percent change in the amount of electrical energy consumed ranged from about −17% to as much as −49%, with an average change of about −31%. Therefore, with the electrical line conditioner 100 installed, an average drop of about 31% electrical energy consumption was recorded.

These tests were repeated in commercial buildings. In one commercial building the amount of energy consumed in a twenty day period prior to installation of the electrical line conditioner 100 was about 9824 KW. After installation of the electrical line conditioner 100 the amount of electrical energy consumed for a twenty day period dropped to 8080 KW for a drop of about 18% of electrical energy consumed. In another commercial building, a drop of about 25% electrical energy consumption was recorded.

It is believed that a harmonic modulation of the electric field produces greater efficiency in conductors, loads and systems, resulting in reduced costs. This technology is not intended to correct and allow for circuit overloading, but the parameters of the experiment that have been set so far exceed the expectations of the conductor performance, so as to more clearly demonstrate the qualities of our product.

The foregoing description of the preferred embodiment of the invention has been presented for the purposes of illustration and description. It is not intended to be exhaustive or to limit the invention to the precise form disclosed. Many modifications and variations are possible in light of the above teaching. It is intended that the scope of the invention not be limited by this detailed description, but by the claims and the equivalents to the claims appended hereto.

### INDUSTRIAL APPLICABILITY

This invention may be industrially applied to the development, manufacture, and use of anodized metal units placed near electrical lines for the purpose of reducing energy consumption without compromising performance of a load. Anodized metal units may comprise aluminum alloy. The invention may comprise at least two anodized metal units, one dyed violet and the other dyed black.

I claim:

1. An energy conservation device, comprising a conditioner unit, wherein the conditioner unit comprises:
a first anodized metal unit; and
a second anodized metal unit; the first and second anodized metal units being positioned near an electrical line, thereby, decreasing the amount of electrical energy required to power a load without diminishing the performance of the load when compared to a non-conditioned electrical line.

2. The energy conservation device of claim 1, wherein the first anodized metal unit is violet and the second anodized metal unit is black.

3. The energy conservation device of claim 2, wherein the first anodized metal unit and the second anodized metal unit each comprises an aluminum alloy.

4. The energy conservation device of claim 3, wherein the aluminum alloy comprises:
at least 80% aluminum;
at least 0.1% magnesium; and
at least 0.05% chromium.

5. The energy conservation device of claim 3, wherein the aluminum alloy comprises:
approximately 90% to approximately 99.5% aluminum;
approximately 0.5% to approximately 5.1% magnesium; and
approximately 0.09% to approximately 0.25% chromium.

6. The energy conservation device of claim 3, wherein the aluminum alloy comprises:
approximately 97.25% aluminum;
approximately 2.5% magnesium; and
approximately 0.25% chromium.

7. The energy conservation device of claim 3 further comprising a spacer mounted on the first and second anodized metal units.

8. The energy conservation device of claim 7 further comprising:
a plurality of conditioner units;
a band supporting the plurality of conditioner units;
a fastener to secure the band to an electrical line;
wherein the first anodized metal unit is positioned adjacent to the second anodized metal unit in each of the plurality of conditioner units and each conditioner unit is relatively oriented on the band such that the first anodized metal units of each conditioner unit are aligned along a first portion of the band and the second anodized metal units of each conditioner unit are aligned along a second portion of the band opposite the first anodized metal units.

9. A method of producing an energy conservation device that decreases an amount of electricity required to power a load without decreasing a performance of the load, comprising the steps of:
anodizing a plurality of metal pieces;
dyeing a first set of metal pieces violet;
dyeing a second set of metal pieces black; and
sealing the plurality of metal pieces; thereby creating an energy conservation device.

10. The method of claim 9, wherein anodizing the plurality of metal pieces comprises the steps of:
placing the plurality of metal pieces on a conductive support member;
soaking the plurality of metal pieces in an alkaline solution comprising approximately 1% to approximately 30% caustic soda for approximately 5 seconds to approximately 30 minutes at approximately 100 degrees Fahrenheit to approximately 200 degrees Fahrenheit;
rinsing off the alkaline solution in water for at least approximately 30 seconds;
soaking the plurality of metal pieces in a cleansing acidic solution comprising approximately 75% to approximately 99% sulfuric acid and approximately 1% to approximately 25% nitric acid for at least 15 seconds;
rinsing off the cleansing acidic solution in water for at least approximately 30 seconds;
electrochemically oxidizing the plurality of metal pieces in an anodizing acidic solution comprising sulfuric acid by applying approximately 15 volts to approximately 21 volts of direct current to the conductive support member at 66 degrees Fahrenheit to approximately 74 degrees Fahrenheit; and
rinsing off the anodizing acidic solution in water for at least approximately 30 seconds.

11. The method of claim 10, wherein dyeing the first set of metal pieces a shade of violet and dyeing the second set of metal pieces a shade of black occur at a temperature of approximately 100 degrees Fahrenheit to approximately 200 degrees Fahrenheit for approximately 30 seconds to approximately 20 minutes and rinsed thereafter for at least 30 seconds in water.

12. The method of claim 11, wherein dyeing the first set of metal pieces a shade of violet further comprises using a dye comprising approximately 2.0 grams/liter to approximately 5.0 grams/liter of a violet dye powder.

13. The method of claim 10, wherein the plurality of metal pieces are sealed with a sealant comprising nickel acetate for approximately 1 minute to approximately 60 minutes at approximately 150 degrees Fahrenheit to approximately 212 degrees Fahrenheit and rinsed thereafter in water for at least 30 seconds.

14. A method of conserving an electrical energy without compromising a performance of a load comprising:
placing at least one anodized metal unit near an electrical line thereby resulting in a reduction in the electrical energy required to power the load without diminishing the performance of the load.

15. The method of claim 14, further comprising: arranging a first anodized metal unit and a second anodized metal unit such that the electrical line is situated between the first anodized metal unit and the second anodized metal unit.

16. The method of claim 14 further comprising:
mounting a second anodized metal unit onto the first anodized metal unit to form a conditioner unit; and
affixing the conditioner unit onto an electrical panel.

17. The method of claim 16 further comprising mounting a spacer on the first anodized metal unit.

18. The method of claim 17, wherein the first anodized metal unit is dyed violet and the second anodized metal unit is dyed black.

19. The method of claim 18, wherein the first and the second anodized metal units are each a metal alloy comprising an aluminum.

20. The method of claim 19, wherein the metal alloy further comprises a magnesium and a chromium.
